(19) United States
(12) Patent Application Publication
(10) Pub. No.: US 2007/0035930 A1
(43) Pub. Date: Feb. 15, 2007

(54) Methods and devices for cooling printed circuit boards

(76) Inventors: Chien-Min Sung, Taipei County (TW); Ming-Chi Kan, Tainan County (TW); Shao Chung Hu, Taipei County (TW)

Correspondence Address: THORPE NORTH & WESTERN, LLP., 8180 SOUTH 700 EAST, SUITE 200, SANDY, UT, 84070, US

(21) Appl. No.: 11/201,771

(22) Filed: Aug. 10, 2005

(51) Int. Cl. H05K 7/20

(52) U.S. Cl. 361/708

(57) ABSTRACT

Methods and devices for cooling printed circuit boards having at least one heat source are disclosed and described. The method can include coating a layer of diamond-like carbon (DLC) over at least a portion of the printed circuit board in order to accelerate movement of heat away from the heat source. Various heat sources may be present on a printed circuit board. In one aspect, the heat source can be an active heat source such as a heat-generating electronic component.

### FIELD OF THE INVENTION

The present invention relates generally to methods and associated devices for cooling printed circuit boards and other electronics devices. Accordingly, the present invention involves the electrical and material science fields.

### BACKGROUND OF THE INVENTION

In many developed countries, major portions of the populations consider electronic devices to be integral to their lives. Such increasing use and dependence has generated a demand for electronics devices that are smaller and faster. As electronic circuitry increases in speed and decreases in size, cooling of such devices becomes problematic.

Electronic devices generally contain printed circuit boards having integrally connected electronic components that allow the overall functionality of the device. These electronic components, such as processors, transistors, resistors, capacitors, light-emitting diodes (LEDs), etc., generate significant amounts of heat. As it builds, heat can cause various thermal problems associated with both the printed circuit board and internally in many electronic components. Significant amounts of heat can affect the reliability of an electronic device, or even cause it to fail by, for example, causing bum out or shorting both within the electronic components themselves and across the surface of the printed circuit board. Thus, the buildup of heat can ultimately affect the functional life of the electronic device. This is particularly problematic for electronic components with high power and high current demands, as well as for the printed circuit boards that support them.

The prior art often employs fans, heat sinks, Peltier and liquid cooling devices, etc., as means of reducing heat buildup in electronic devices. As increased speed and power consumption cause increasing heat buildup, such cooling devices generally must increase in size to be effective and also require power in and of themselves to operate. For example, fans must be increased in size and speed to increase airflow, and heat sinks must be increased in size to increase heat capacity and surface area. The demand for smaller electronic devices, however, not only precludes increasing the size of such cooling devices, but may also require a significant size decrease.

As a result, methods and associated devices are being sought to provide adequate cooling of electronic devices while minimizing size and power constraints placed on such devices due to cooling.

### SUMMARY OF THE INVENTION

Accordingly, the present invention provides a method of cooling a printed circuit board having at least one heat source. The method can include coating a layer of diamond-like carbon (DLC) over at least a portion of the printed circuit board in order to accelerate movement of heat away from the heat source. Various heat sources may be present on a printed circuit board. In one aspect, the heat source can be an active heat source. One example of an active heat source is a heat-generating electronic component.

In one aspect of the present invention, the accelerated movement of heat away from the heat source is at least partially due to heat movement laterally through the DLC layer. The movement of heat away from the heat source may be further accelerated at least partially by the movement of heat from the DLC layer to the air. In one aspect, the movement of heat from the DLC layer to air can be greater than heat movement from the printed circuit board to air. In another aspect, the movement of heat from the printed circuit board to the DLC layer can be greater than heat movement from the printed circuit board to air.

The DLC layer can be coated over any portion of the printed circuit board to produce a cooling effect. In one aspect, the DLC layer can be coated over at least one conductive trace. In another aspect, the DLC layer can be coated on two sides of the printed circuit board.

Other heat conductive materials can also be utilized to cool printed circuit boards according to the present invention. For example, in one aspect a method of cooling a printed circuit board having at least one heat source is provided that can include coating a layer of a ceramic material over at least a portion of the printed circuit board in order to accelerate movement of heat away from the heat source. Various ceramic materials can be utilized as heat conductive materials according to the present invention. In one aspect, the ceramic material can be an oxide. Oxides can include any useful oxide known to one skilled in the art, including Al₂O₃, MgO, BeO, ZnO, and combinations thereof. In another aspect, the oxide can be Al₂O₃. The ceramic material can also include a carbide. In one aspect, the carbide can include SiC, TiC, and combinations thereof. In another aspect, the carbide can be SiC. The ceramic material can also include a nitride. In one aspect, the nitride can include AlN, TiN, ZrN, TiCN, TiAlN, Si₃N₄ and combinations thereof. In another aspect, the nitride is AlN.

The present invention also provides thermally dynamic printed circuit boards for minimizing heat buildup. Such devices can include a printed circuit board having at least one heat source, and a layer of heat conductive material coated on the printed circuit board. The layer of heat conductive material can be thermally coupled to the at least one heat source such that the layer of heat conductive material accelerates heat movement away from the heat source. Furthermore, the heat conductive material can include any useful material known to one skilled in the art, including, the materials recited herein.

In one embodiment of the present invention, a light-emitting diode (LED) device having improved heat dissipation properties is provided. The LED device can include a printed circuit board having at least one LED coupled thereto, and a layer of DLC coated on the printed circuit board. The printed circuit board can be a metal core printed circuit board. The layer of DLC can be exposed to air and thermally coupled to the at least one light-emitting diode such that the layer of DLC accelerates heat movement away from the light-emitting diode. In one aspect, the accelerated movement of heat away from the LED is at least partially due to heat movement laterally through the DLC layer. In another aspect, the accelerated movement of heat away from the LED is at least partially due to heat movement from the DLC layer to air. In yet another aspect, the heat movement from the DLC layer to air is greater than heat movement from the printed circuit board to air. In a further aspect, heat movement from the printed circuit board to the DLC layer is greater than heat movement from the printed circuit board to the air.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-section view of a printed circuit board in accordance with one embodiment of the present invention.

FIG. 2 is a cross-section view of a printed circuit board in accordance with one embodiment of the present invention.

FIG. 3 is a cross-section view of a printed circuit board in accordance with one embodiment of the present invention.

FIG. 4 is a cross-section view of a printed circuit board in accordance with one embodiment of the present invention.

FIG. 5 is a cross-section view of an LED device on a metal core printed circuit board in accordance with one embodiment of the present invention.

### DETAILED DESCRIPTION OF THE INVENTION

Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a heat source” includes reference to one or more of such sources, and reference to “the DLC layer” includes reference to one or more of such layers.

The terms “heat transfer,” “heat movement,” and “heat transmission” can be used interchangeably, and refer to the movement of heat from an area of higher temperature to an area of cooler temperature. It is intended that the movement of heat include any mechanism of heat transmission known to one skilled in the art, such as, without limitation, conductive, convective, radiative, etc.

As used herein, the term “heat conductive material” refers to any material known to one skilled in the art that is capable of conducting heat at a higher rate than the material on which it is deposited.

As used herein, “dynamic” or “dynamically” or “thermally dynamic” refers to a characteristic of a material wherein the material is active at transferring energy. Generally, the dynamic material is active at transferring thermal energy.

As used herein, “heat source” refers to a device or object having an amount of thermal energy or heat which is greater than an immediately adjacent region. In printed circuit boards, for example, a heat source can be any region of the board that is hotter than an adjacent region. Heat sources can include devices that produce heat as a byproduct of their operation (hereinafter known as “primary heat sources” or “active heat sources”), as well as objects that become heated by a transfer of heat energy thereto (hereinafter known as “secondary heat sources” or “passive heat sources”). Examples of primary or active heat sources include without limitation, CPU's, electrical traces, LED's, etc. Examples of secondary or passive heat sources include without limitation, heat spreaders, heat sinks, etc.

As used herein, the terms “conductive trace” and “conduction trace” refer to conductive pathways on a printed circuit board that are capable of conducing heat, electricity, or both.

The term “ceramic” refers to a compound of nonmetallic and metallic or semimetallic elements, for which the interatomic bonding is predominantly ionic. Ceramic also includes cermet materials.

As used herein, “vapor deposition” refers to a process of depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically depositing diamond particles in a vapor form upon a surface. Various CVD techniques are well known in the art.

As used herein, “physical vapor deposition,” or “PVD” refers to any method of physically depositing diamond particles in a vapor form upon a surface. Various PVD techniques are well known in the art.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including its physical and electrical properties are well known in the art.

As used herein, “distorted tetrahedral coordination” refers to a tetrahedral bonding configuration of carbon atoms that is irregular, or has deviated from the normal tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, tungsten, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

As used herein, “coat,” “coating,” and “coated,” with respect to a printed circuit board, refers to an area along at least a portion of an outer surface of the printed circuit board that has been intimately contacted with a layer of heat conductive material, and, as such, thermal coupling has been achieved. In some aspects, the coating may be a layer which substantially covers an entire surface of the printed circuit board. In other aspects, the coating may be a layer which covers only a portion of a surface of the printed circuit board.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 micron to about 5 microns” should be interpreted to include not only the explicitly recited values of about 1 micron to about 5 microns, but also include individual values and sub-ranges within the indicated range. Thus, included in this numerical range are individual values such as 2, 3, and 4 and sub-ranges such as from 1-3, from 2-4, and from 3-5, etc.

This same principle applies to ranges reciting only one numerical value. Furthermore, such an interpretation should apply regardless of the breadth of the range or the characteristics being described.

The Invention

The present invention provides methods of cooling printed circuit boards and associated devices. The inventors have found that materials having high thermal conductivity can be coated onto the surface of a printed circuit board in order to accelerate heat transfer laterally away from hot spots. Many of these materials, particularly diamond-like carbon (DLC), also accelerate heat transfer to the air. Thus a printed circuit board can be effectively cooled by accelerated heat transfer laterally across the surface of the board and accelerated heat transfer to the air as it spreads laterally.

In one aspect of the present invention, a method of cooling a printed circuit board having at least one heat source is provided. The method can include coating a layer of DLC over at least a portion of the printed circuit board in order to accelerate movement of heat away from the heat source. Any form of heat source known to introduce heat into a printed circuit board known to one skilled in the art is considered to be within the scope of the present invention. In one aspect the heat source can be an active heat source, and example of which may be a heat-generating electronic component. Such components may include, without limitation, resistors, capacitors, transistors, processing units including central and graphics processing units, LEDs, lazer diodes, filters, etc. Heat sources can also include regions of the printed circuit board containing a high density of conductive traces, and regions receiving transmitted heated from a heat source that is not in physical contact with the printed circuit board. They can also include heat sources in physical contact with but not considered integral to the printed circuit board. An example of this may be a motherboard having a daughterboard coupled thereto, where heat is transferred from the daughterboard to the motherboard.

Irrespective of the source, the transfer of heat present in the printed circuit board can be accelerated away from the heat source by coating the printed circuit board with a layer of DLC. It should be noted that the present invention is not limited as to specific theories of heat transmission. As such, in one aspect the accelerated movement of heat away from the heat source can be at least partially due to heat movement laterally through the diamond-like carbon layer. Due to the heat conductive properties of DLC, heat can rapidly spread laterally through the DLC layer across the surface of the printed circuit board. In another aspect, the accelerated movement of heat away from the heat source is at least partially due to heat movement from the DLC to air. DLC has exceptional heat emissivity characteristics even at temperatures below 100° C., and as such, may radiate heat directly to the air. Many other materials, particularly the resins, ceramics, and other materials that may be included in a printed circuit board, conduct heat much better than they emit heat. As such, heat can be conducted through the printed circuit board materials to the DLC and subsequently emitted to the air. Due to the high heat conductive and radiative properties of DLC, heat movement from the DLC layer to air can be greater than heat movement from the printed circuit board to air. Also, heat movement from the printed circuit board to the diamond-like carbon layer can be greater than heat movement from the printed circuit board to the air. As such, the layer of DLC can serve to accelerate heat transfer away from a heat source more rapidly than heat can be transferred through the printed circuit board itself, or from the printed circuit board to the air. Such accelerated heat transfer may result in printed circuit boards with much cooler operational temperatures.

The acceleration of heat transfer away from a heat source not only cools the printed circuit board, but also may reduce the heat load on many electronic components that are cooled primarily to the air opposite the printed circuit board. For example, a central processing unit (CPU) having an external heat sink and fan may require less external cooling due to the improved heat transmission through the printed circuit board via the CPU socket.

The layer of DLC can be coated on various portions of the printed circuit board, depending on factors such as the board intended use, potential temperatures the board may attain, manufacturing costs, etc. As will be discussed further below, DLC can be coated on one or more conductive trace, a portion, one side, or both sides of the printed circuit board.

The present invention also contemplates methods of cooling a printed circuit board having at least one heat source, including coating a layer of a ceramic material over at least a portion of the printed circuit board in order to accelerate movement of heat away from the heat source. Though the thermal properties of ceramic materials are inferior to the thermal properties DLC, they may be sufficient for cooling printed circuit boards used in many applications. Ceramic materials are believed to radiate heat more effectively than they conduct it. As such, heat dissipation from a printed circuit board coated with a ceramic material may be primarily by heat radiation from the ceramic surface rather than heat conduction laterally through the ceramic and away from the heat source. Given the greater expense of coating a printed circuit board with DLC, it may be financially beneficial to utilize DLC in applications utilizing high power, where heat buildup may be critical. On the other hand, relatively low-power applications may not warrant the expense of utilizing DLC coatings. In situations such as these, ceramic coatings can be utilized to cool printed circuit boards at a lower expense.

Any ceramic material known to one skilled in the art having favorable heat conduction properties can be utilized to cool printed circuit boards as disclosed herein. In one aspect, the ceramic material can include an oxide. Numerous oxides are contemplated, including, but not limited to Al₂O₃, MgO, BeO, ZnO, and combinations thereof. One example of a useful oxide is Al₂O₃. In another aspect, the ceramic material can include a carbide. Carbides are well known to those skilled in the art, and may include, without limitation, SiC, TiC, WC, BC and combinations thereof. One example of a useful carbide is SiC. In yet another aspect, the ceramic material can include a nitride. Various nitrides are contemplated, including, but not limited to AlN, TiN, ZrN, TiCN, TiAlN, Si₃N₄, BN, and combinations thereof. One example of a useful nitride is AlN.

The layers discussed herein can be formed using any number of known techniques such as, but not limited to, vapor deposition, thin film deposition, preformed solids, powdered layers, screen printing, or the like. In one aspect, a layer can be formed using deposition techniques such as PVD, CVD, or any other known thin-film deposition process. In one aspect, the PVD process is sputtering or cathodic arc. Additionally, the layers can be brazed, glued, or otherwise affixed to the printed circuit board using methods which do not interfere with the thermal conductivity of the material.

With respect to DLC layers, a number of specific methods and techniques are known for deposition onto a substrate including physical vapor deposition (PVD) and chemical vapor deposition (CVD). In accordance with the present invention, any suitable deposition process may be used to create the DLC layer. Further, specific deposition conditions may be used in order to adjust the exact type of material to be deposited, whether DLC, amorphous diamond, or pure diamond. In one embodiment, a DLC layer may be deposited onto a printed circuit board through a PVD sputtering process. In another embodiment, the DLC layer may be deposited by a thermal evaporation PVD process.

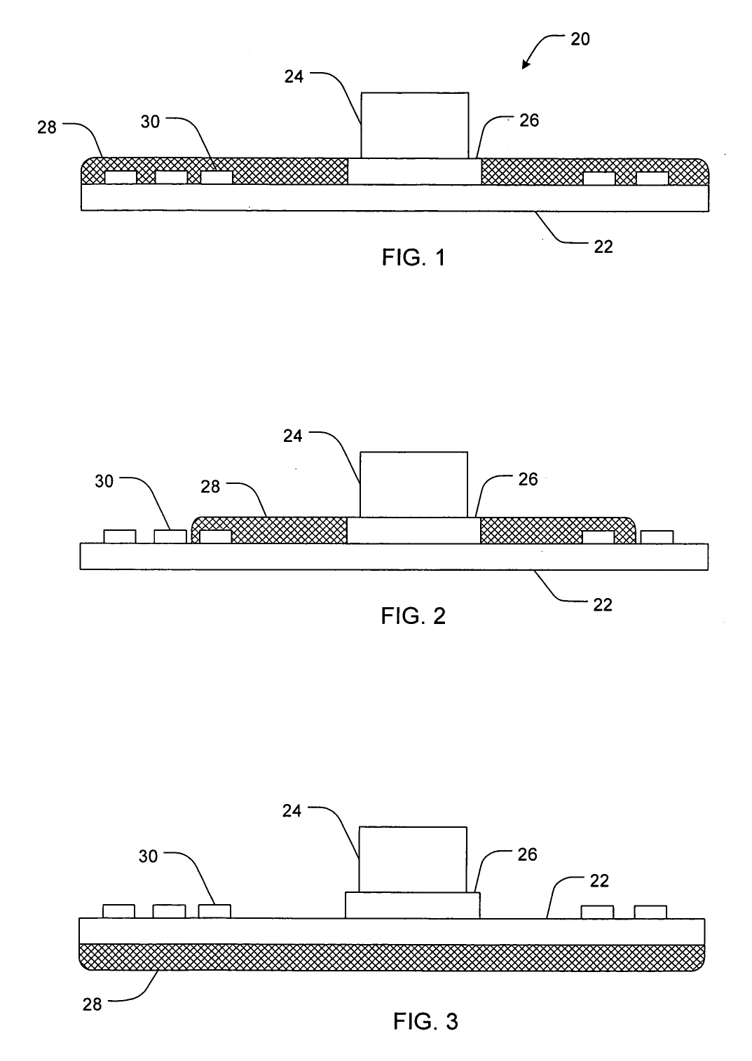

The present invention also contemplates printed circuit boards and other electronic devices cooled by the methods described herein. In one embodiment of the present invention, a thermally dynamic printed circuit board device 20 for minimizing heat buildup as shown in FIG. 1. The device 20 may include a printed circuit board 22 having at least one heat source 24. The heat source shown in FIG. 1 is an active heat source such as an electronic component. It is also contemplated that the heat source may be merely a hot spot on the printed circuit board (not shown). The heat source 24 may be coupled to the printed circuit board 22 by a conductive contact 26. The conductive contact 26 may be an electrical contact, a thermal contact, or both. The conductive contact 26 is merely intended to illustrate a conductive pathway for heat to move from the heat source 24 to the printed circuit board 22.

A layer of heat conductive material 28 can be coated on the printed circuit board 22 by any means known to one skilled in the art. The layer of heat conductive material 28 is thermally coupled to the heat source 24 such that the layer of heat conductive material 28 can accelerate heat movement away from the heat source 24. A heat conductive material is selected such that it has high thermal conductivities. As such, heat generated by the heat source 24 is accelerated laterally through the heat conductive material 28 away from the heat source. Though any material known to one skilled in the art having beneficial heat conductive properties, specific examples include DLC, ceramics, and combinations thereof. In one aspect, the heat conductive material may be DLC. In another aspect, the heat conductive material is a ceramic material. As described herein, ceramic materials can include oxides such as Al₂O₃, MgO, BeO, ZnO; carbides such as SiC, TiC; and nitrides such as AlN, TiN, ZrN, TiCN, TiAlN, Si₃N₄. The layer of heat conductive material 28 can be of any thickness that would allow cooling according to the methods and devices of the present invention. Thicknesses may vary depending on the application and the printed circuit board configuration. For example, greater cooling requirements may require a thicker layer of the heat conductive material. The thickness may also vary depending on the heat conductive material chosen. For example, thicker layers of ceramic materials may be required to achieve cooling as compared to thinner, more thermally efficient DLC coatings. That being said, in one aspect the layer of DLC can be from about 0.1 micrometer to about 50 micrometers thick. In another aspect, the layer of DLC can be from about 0.1 micrometer to about 10 micrometers thick.

The heat conductive material 28 can be coated on the printed circuit board 22 in various configurations. In one aspect, the heat conductive material 28 can be coated over at least one conductive trace 30. This configuration would have the added benefit of accelerating heat movement away from coated conductive traces 30 and into the heat conductive material 28. The heat conductive material 28 can cover essentially all of a surface of the printed circuit board 22 as shown in FIG. 1, or it can be coated on only a portion, or selected portions, of the surface as shown in FIG. 2. In this aspect, regions surrounding heat sources or hot spots on the printed circuit board can be locally coated and thus lower manufacturing costs, particularly for DLC coatings.

As shown in FIG. 3, it is also contemplated that a heat conductive material 28 can be coated on a printed circuit board 22 on a side opposite to a heat source 24. Such a configuration can accelerate the transfer of heat from the printed circuit board 22 into the heat conductive material 28 and away from the heat source 24. This may be useful in situations where a layer of heat conductive material on the heat source side may interfere with the functionality of the printed circuit board.

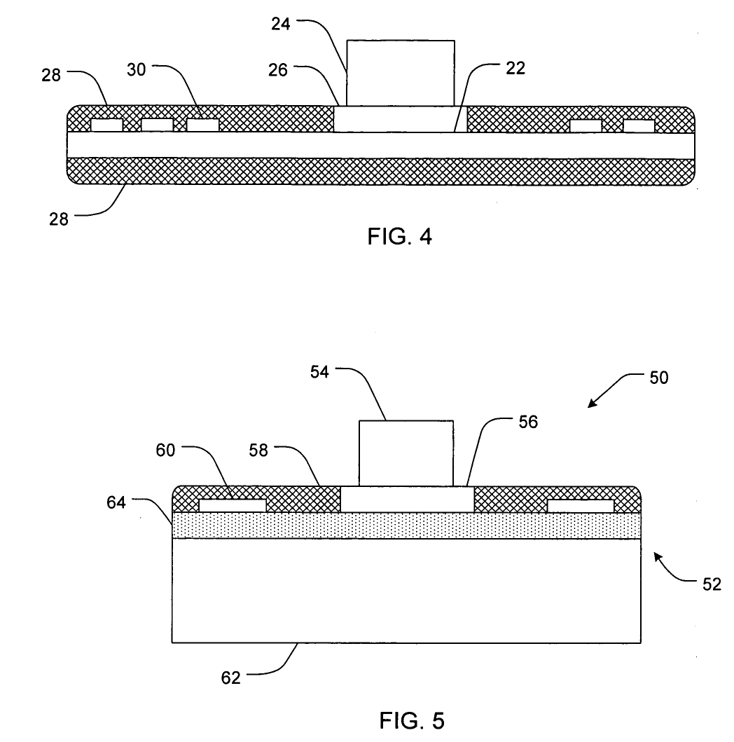

As shown in FIG. 4, a heat conductive material 28 may be coated on both sides of a printed circuit board 22. Such a configuration may function to more efficiently cool the printed circuit board 22 by accelerating the movement of heat into layers of heat conductive material 28 on both sides. As such, in one aspect the heat conductive material is two layers of DLC coated on opposite sides of the printed circuit board.

It is also contemplated that the present invention includes aspects involving LED devices. As they have become increasingly important in electronics and lighting devices, LEDs continue to be developed that have ever increasing power requirements. This trend of increasing power has created cooling problems for these devices. These cooling problems can be exacerbated by the typically small size of these devices, which may render heat sinks with traditional aluminum heat fins ineffective due to their bulky nature. As an alternative, the inventors have discovered that a coating of DLC on the printed circuit boards of these devices allows adequate cooling even at very high power, while maintaining a small LED package size.

As such, as shown in FIG. 5, one aspect of the present invention may include an LED device 50 having improved heat dissipation properties. The LED device 50 may include a printed circuit board 52 having at least one LED 54 coupled thereto. The LED 54 may be coupled to the printed circuit board 52 by a conductive contact 56. The conductive contact 56 may be an electrical contact, a thermal contact, or both. The conductive contact 56 is merely intended to illustrate a conductive pathway for heat to move from the LED 54 to the printed circuit board 52. The printed circuit board 52 may be a metal core printed circuit board, including a metal substrate 62 topped with an adhesive coating 64. The metal substrate 62 can be any material known to be useful to one skilled in the art. One example of a metal substrate can be aluminum. The adhesive coating 64 can be any adhesive known to one skilled in the art that can function to bond conductive traces 60, conductive contacts 56, etc., to the metal substrate 62. One example of an adhesive coating 64 may be an epoxy.

The LED device 50 may further include a layer of DLC 58 coated on the printed circuit board 52 and exposed to air. The layer of DLC 58 can be coated across essentially all of a surface, or it may be coated across only a portion of a surface of the printed circuit board 52. In one aspect, the layer of DLC 58 can be coated over at least one conductive trace 60. In another aspect, the layer of DLC 58 can be coated over at least one conductive contact 56. The layer of DLC 58 can be thermally coupled to the LED 54 such that it accelerates heat movement away from the LED or any other heat source present on the printed circuit board 52. In one aspect, the accelerated movement of heat away from the LED 54 is at least partially due to heat movement laterally through the layer of DLC 58. In another aspect, the accelerated movement of heat away from the LED 54 is at least partially due to heat movement from the layer of DLC 58 to the air. Even at temperatures below 100° C., DLC has exceptional heat emissivity characteristics that may allow direct radiation of heat to the air. As such, heat generated by the LED can be conducted through the printed circuit board to the DLC and quickly emitted to the air. In yet another aspect, the heat movement from the layer of DLC 58 to the air is greater than the heat movement from the printed circuit board 52 to the air. In a further embodiment, the heat movement from the printed circuit board 52 to the layer of DLC 58 is greater than the heat movement from the printed circuit board 52 to the air.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of cooling a printed circuit board having at least one heat source, comprising:
coating a layer of diamond-like carbon over at least a portion of the printed circuit board in order to accelerate movement of heat away from the heat source.

2. The method of claim 1, wherein the heat source is an active heat source.

3. The method of claim 2, wherein the active heat source is a heat-generating electronic component.

4. The method of claim 1, wherein the accelerated movement of heat away from the heat source is at least partially due to heat movement laterally through the diamond-like carbon layer.

5. The method of claim 1, wherein the accelerated movement of heat away from the heat source is at least partially due to heat movement from the diamond-like carbon layer to air.

6. The method of claim 5, wherein heat movement from the diamond-like carbon layer to air is greater than heat movement from the printed circuit board to air.

7. The method of claim 1, wherein heat movement from the printed circuit board to the diamond-like carbon layer is greater than heat movement from the printed circuit board to the air.

8. The method of claim 1, wherein coating the layer of diamond-like carbon includes coating the layer of diamond-like carbon over at least one conductive trace.

9. The method of claim 1, wherein coating the diamond-like carbon layer includes coating the diamond-like carbon layer on two sides of the printed circuit board.

10. A method of cooling a printed circuit board having at least one heat source, comprising:
coating a layer of a ceramic material over at least a portion of the printed circuit board in order to accelerate movement of heat away from the heat source.

11. The method of claim 10, wherein the ceramic material is an oxide.

12. The method of claim 11, wherein the oxide includes a member selected from the group consisting of Al₂O₃, MgO, BeO, ZnO, and combinations thereof.

13. The method of claim 12, wherein the oxide is Al₂O₃.

14. The method of claim 10, wherein the ceramic material is a carbide.

15. The method of claim 14, wherein the carbide includes a member selected from the group consisting of SiC, TiC, WC, BC and combinations thereof.

16. The method of claim 15, wherein the carbide is SiC.

17. The method of claim 10, wherein the ceramic material is a nitride.

18. The method of claim 17, wherein the nitride includes a member selected from the group consisting of AlN, TiN, ZrN, TiCN, TiAlN, Si₃N₄, BN and combinations thereof.

19. The method of claim 18, wherein the nitride is AlN.

20. A thermally dynamic printed circuit board device for minimizing heat buildup, comprising:
a printed circuit board having at least one heat source; and
a layer of heat conductive material coated on the printed circuit board, the layer of heat conductive material being thermally coupled to the at least one heat source such that the layer of heat conductive material accelerates heat movement away from the heat source, the heat conductive material including a member selected from the group consisting of diamond-like carbon, ceramics, and combinations thereof.

21. The device of claim 20, wherein the heat conductive material is diamond-like carbon.

22. The device of claim 20, wherein the heat conductive material is a ceramic material.

23. The device of claim 22, wherein the ceramic material is an oxide.

24. The device of claim 23, wherein the oxide includes a member selected from the group consisting of Al₂O₃, MgO, BeO, ZnO, and combinations thereof.

25. The device of claim 24, wherein the oxide is Al₂O₃.

26. The device of claim 22, wherein the ceramic material is a carbide.

27. The device of claim 26, wherein the carbide includes a member selected from the group consisting of SiC, TiC, WC, BC and combinations thereof.

28. The device of claim 27, wherein the carbide is SiC.

29. The device of claim 22, wherein the ceramic material is a nitride.

30. The device of claim 29, wherein the nitride includes a member selected from the group consisting of AlN, TiN, ZrN, TiCN, TiAlN, Si₃N₄, BN and combinations thereof.

31. The device of claim 30, wherein the nitride is AlN.

32. The device of claim 21, wherein the layer of diamond-like carbon is two layers of diamond-like carbon coated on opposite sides of the printed circuit board.

33. The device of claim 21, wherein the layer of diamond-like carbon is from about 0.1 micrometer to about 50 micrometer thick.

34. The device of claim 33, wherein the layer of diamond-like carbon is from about 0.1 micrometer to about 10 micrometer thick.

35. A light-emitting diode device having improved heat dissipation properties, comprising:
a printed circuit board having at least one light-emitting diode coupled thereto; and
a layer of diamond-like carbon coated on the printed circuit board and exposed to air, the layer of diamond-like carbon being thermally coupled to the at least one light-emitting diode such that the layer of diamond-like carbon accelerates heat movement away from the light-emitting diode.

36. The device of claim 35, wherein the printed circuit board is a metal core printed circuit board.

37. The device of claim 35, wherein the accelerated movement of heat away from the light-emitting diode is at least partially due to heat movement laterally through the layer of diamond-like carbon.

38. The device of claim 35, wherein the accelerated movement of heat away from the light-emitting diode is at least partially due to heat movement from the layer of diamond-like carbon to air.

39. The device of claim 38, wherein heat movement from the layer of diamond-like carbon to air is greater than heat movement from the printed circuit board to air.

40. The device of claim 35, wherein heat movement from the printed circuit board to the layer of diamond-like carbon is greater than heat movement from the printed circuit board to the air.

41. The device of claim 35, wherein the layer of diamond-like carbon is coated over at least one conductive trace.
